(19) United States
(12) Patent Application Publication
(10) Pub. No.: US 2005/0045914 A1
(43) Pub. Date: Mar. 3, 2005

(54) Flip chip device assembly machine

(75) Inventors: Edward Agranat, Weston, MA (US); Matthew Bouche, Tyngsboro, MA (US); Dennis Carew, Burlington, MA (US); Nicholas Celia, Avon, MA (US); Michael Chalsen, N. Billerica, MA (US); Cyriac Devasia, Nashua, NH (US); Brian Evans, Marshfield, MA (US); David Greco, Saugus, MA (US); Gheorghe Pascariu, Summer Hill (SG); Russell Wheeler, Concord, MA (US)

Correspondence Address: STOEL RIVES LLP, 900 SW FIFTH AVENUE, SUITE 2600, PORTLAND, OR, 97204, US

(73) Assignee: Newport Corporation, Irvine, CA (US)

(21) Appl. No.: 10/888,520

(22) Filed: Jul. 8, 2004

Related U.S. Application Data
(60) Provisional application No. 60/486,688, filed on Jul. 9, 2003.

(51) Int. Cl. H01L 29/739

(52) U.S. Cl. 257/200

(57) ABSTRACT

A flip chip assembly machine (FCAM) (30) includes a main gantry (50) and a substrate camera gantry (40) that are configured to operate independently of each other and, respectively, support a die (12) and a substrate camera (38) for alignment purposes. The FCAM further includes a fluxer (130) for applying flux to the die. A flip-to-flux pick and place subassembly (116) picks up a die and places it in flux (46) independently of the operation of the main gantry, which may perform another task during the flux dwell time. A substrate carrier conveyor (154) includes a walking beam (260) to rapidly accelerate and decelerate substrate carrier movement into and out of the FCAM.

### RELATED APPLICATION

This application claims benefit of U.S. Provisional Application No. 60/486,688, filed Jul. 9, 2003.

### TECHNICAL FIELD

This invention relates to microelectronics device assembly and, in particular, to a flip chip (FC) device assembly machine and related processes.

### BACKGROUND OF THE INVENTION

Product functionality for devices such as handheld telephones, laptop computers, and other personal electronic items has driven a trend towards compactness of design and improved packaging processes. Flip chip technology offers design and processing advantages. Design advantages include smaller device footprint, improved electrical performance, better thermal dissipation properties, and lower cost resulting from better use of silicon real estate. Processing advantages include shorter assembly cycle times, fewer operations, and higher yields.

A range of packages is available for flip chip packaging including FC-chip scale packaging (FC-CSP), FC-ball grid arrays (FC-BGA), high-performance FC-BGAs (HFC-BGA), and FC pin grid arrays (FC-PGA) among others. These packages can be compared with reference to I/O count and package size. The methodology of flip chip die bonding is rooted in die bonding with certain modifications. There are critical requirements for high volume flip chip die bonding. Key components of the flip chip process are substrate handling, die flipping, and flux dipping and are described from the initial point of picking the die through fluxing and to the actual placement of the die, including material handling. Work holder planarity and flux control represent aspects of the flip chip die bonding process that materially affect high yield, high volume production. Process control and high throughputs represent aspects of underfill dispensing that materially affect cost effective production.

There is a rapid increase in the number of electronic packages implemented with flip chip technology. The ongoing expansion of the Internet, mobile phones, personal data assistants, desktop and laptop computers, digital camcorders, digital cameras, and other electronic based consumer products has spurred a revolution of innovation in flip chip technology. Product functionality has never been more demanding, and time to market and volume production is more critical than ever. Flip chip packages exist for a range of products from few-lead radio-frequency identification devices to greater than 2000 lead BGAs. Substrate technology has transitioned from traditional ceramics to a wide range of organic materials, thereby enabling a multitude of different package applications built around flip chip technology.

There are a number of inherent advantages of flip chip technology. A key advantage of flip chip technology is size. Flip chip packages do not require peripheral space for the wire bonds and, therefore, can be made smaller than wire bond packages with a similar input/output (I/O) count. For die with a high I/O count, flip chip technology offers large space savings because the I/O can be arranged in an array on the die and the substrate. This eliminates the need for traces to the chip edge from internal interconnect points. At the substrate level, routings can be directed through multiple internal layers. This array architecture can be used to achieve space savings, similar to the savings between BGA and quad flat pack (QFP) packaging. Ultimately, when taking into account die shrinkage enabled by flip chip, overall material cost (package and die) is less. Flip chip technology also offers the potential for lower total package height because no extra clearance is required for wire bonds or encapsulation/mold compound above the die. The space savings of flip chip technology translate into a geometry that delivers the solution for today's high I/O consumer end products, such as digital video cameras.

Another advantage is improved performance. A short signal path provides for low inductance, resistance, and capacitance, resulting in faster signal and better high frequency characteristics. Flip chip technology provides improved functionality in terms of an increased number of I/Os and the concentration of more signal, ground, and power connections in a smaller area. The technology offers better thermal capabilities, since an external heat sink can be directly added above the chip to remove heat.

A further advantage is that a solder reflow flip chip has fewer process steps compared to traditional epoxy die attach and wire bonding. Operations such as wire bonding and encapsulation or molding are eliminated. Flip chip technology integrates all package assembly steps in one operation. The assembly time, total number of process steps, overall capital equipment costs, the number of pieces of equipment, as well as other factors, result in a reduced cost of ownership.

As stated above, there are multiple types of flip chip packages, including FC-BGA, HFC-BGA, ceramic FC-BGA/PGA, and FC-CSP. FC-BGA and HFC-BGA packages support I/Os of 100 to over 1500 with bismaleimide triazine (BT) laminate or sophisticated multi-layer substrates. HFC-BGA packages are thermally enhanced by the attachment of a metal heat sink that can effectively remove the heat and improve thermal characteristics. Ceramic FC-BGA/PGA is a ceramic package that provides better heat dissipation for high thermal conductivity and a coefficient of thermal expansion more closely matched to that of silicon. The FC-CSP package offers chip scale geometry for packages with fewer than 200 I/Os and provides better protection for the die than chip on board (COB) technology. FC-CSP prevails over known good die in low-cost test and burn-in. It is intended to provide thin, small profile, and lightweight packaging. Applications include RF and memory integrated circuits (ICs).

Table 1 below summarizes the characteristics of these types of flip chip packages.

TABLE 1
Common Flip Chip Packages

| Package | | | Substate | Ball |
|---|---|---|---|---|
| Type | Nr. I/O | Package size | Type | Pitch |
| FC-CSP | 36˜200 | 7 × 7˜15 × 15 | Laminate | 0.8/1.0 |
| Ceramic FC | <1421 | 27 × 27˜50 × 50 | Ceramic | 0.8˜ |
| BGA/PGA | | | | 1.27 |
| FC-BGA | 100˜1521 | 11 × 11˜40 × 40 | Laminate | 1.0/1.27 |
| HFC-BGA | 256˜1521 | 27 × 27˜40 × 40 | Laminate | 1.0/1.27 |

What is still needed is next generation flip chip production equipment, including flip chip bonders. Future flip chip assembly machines require many advanced features to satisfy the new manufacturing requirements and to minimize the cost of ownership of integrated device manufacturers and subcontract manufacturers.

### SUMMARY OF THE INVENTION

An object of this invention is, therefore, to provide an apparatus and a method for high-throughput flip chip assembly of electronic components.

Another object of this invention is to provide an apparatus and a method for applying flux to the electronic components prior to their assembly.

A further object of this invention is to provide a flip-to-flux pick and place subassembly for further improving electronic component assembly throughput.

Still another object of this invention is to provide a substrate carrier conveyor assembly for rapidly conveying the movement of carriers into and out of the flip chip assembly machine.

A flip chip assembly machine (“FCAM”) is a piece of equipment responsible for picking a die from a wafer, flipping the die, dipping it into flux, and placing it in proper alignment on the substrate. A next generation FCAM offers 300 mm (12 in) wafer capability. The first step in a die bond process is to load substrates to the FCAM. Substrates are unloaded from magazines and indexed into the FCAM. High system speeds are possible when the substrate loading operation can be done in parallel with pick and place operations. The loader is configured to handle substrates in strip form (e.g., BGA strip) as well as singulated substrates in carrier boats. Carrier boats or substrates are loaded into magazines, and the magazines are placed in the loader. The carrier boats are then indexed, one at a time, into the flip chip die bonder.

The substrate strip or carrier is indexed into the work area, and the substrates are locked in place with vacuum pressure using a vacuum chuck. Alternatively, mechanical clamping is sometimes used. The vacuum chuck is manufactured to have very good planarity relative to the die placement head, which places a die on a substrate. A vacuum chuck that is easy to exchange and set up ensures rapid changeover capability. Vacuum sensing ensures that the substrates are secured at all times to enable accurate placement. Use of a “down facing” camera to align the substrates affords an accurate die placement capability. The FCAM determines the substrate coordinates, using substrate fiducials or alignment marks. Most die bonder systems currently use pattern recognition in addition to geometric feature recognition. Pixel size and vision repeatability are factors that affect accuracy. Quality optics and programmable-intensity lighting, together with various light types and colors, are used to obtain better definition.

Die are presented in wafer format with the bumps up. At this stage, wafers have been fully tested and diced. “Good die” on the wafer are either determined by an ink dot scheme or based on a wafer result map. Electronic wafer mapping is usually preferred over ink dot when processing flip chip die. The handling of 300 mm (12 in) wafers includes an ability to dock an industry standard wafer cassette Personal Guided Vehicle. The wafer is loaded from a wafer cassette (which can hold up to 25 wafers), onto a wafer table. During the loading process, a bar code located on the wafer frame is read to cause a download of the correct wafer map file from the server. The wafer is stretched to prevent die edge chipping, and the first good die is located using a wafer camera. The wafer table is indexed to the correct location for a die flipping mechanism to pick and flip the die. The wafer map file (cyber wafer) is aligned to the wafer, and the machine begins to pick good die.

FIGS. 1A, 1B, 1C, and 1D show a die flipping process employed by this invention. FIG. 1A shows a die flipper 10 picking a good die 12 from a wafer 14 having multiple die with solder bumps 16 facing up. A die ejector 18 is positioned under good die 12 and projects ejector pins 20 to separate good die 12 from wafer 14. FIG. 1B shows die flipper 10 attached to good die 12 by vacuum pressure and flipping good die 12 over so that solder bumps 16 are facing down. Die flipper 10 then releases its vacuum pressure. FIGS. 1C and 1D show a flux head 22 attaching to good die 12 by vacuum pressure and lifting good die 12 off die flipper 10 with solder bumps 16 facing down in a flux-ready orientation.

After picking good die 12 from wafer 14, die flipper 10 moves straight up before translating to a rotational movement. This prevents good die 12 from colliding with other die on wafer 14. The vacuum actuated pickup tool on die flipper 10 must not damage solder bumps 16 while having sufficient vacuum pressure to securely hold good die 12 during flipping. Die flipper 10 movement, speed, and acceleration are programmed and synchronized with die ejector 18 and ejector pin 20 movements to prevent die damage and maximize throughput.

FIGS. 2A, 2B, and 2C show a flux dipping process employed by this invention. As shown in FIG. 1D, good die 12 is lifted from die flipper 10 by flux head 22 (or by a bond head if flip-to-flux pick and place not used). FIG. 2A shows flux head 22 positioning good die 12 over a flux well 24. FIG. 2B shows flux head 22 dipping solder bumps 16 of good die 12 into flux well 24. Flux head 22 then moves back into position to retrieve the next good die from die flipper 10 as shown in FIG. 1D. FIG. 2C shows a bond head 26 withdrawing good die 12 from flux well 24. Flux well 24 is a precision-machined depression in a plate that is part of a fluxer that is described with reference to FIG. 9. The flux thickness is determined by the depth of flux well 24 and the surface tension of the fluxing fluid. A range of plates can be exchanged to achieve different thicknesses. The flux delivery system improves yield and throughput. Fine control over the depth of flux is achievable with attention to the properties of the flux and to the mechanics of the delivery system. By programming the speeds of die dipping and depositing flux in flux well 24, throughput can be optimized while still attaining precise control over volume. Fluxer indexing speed is programmed to account for different flux viscosities. Heating the flux can help to reduce flux viscosity and thereby achieve optimum wetting of solder bumps 16.

Fluxer planarity contributes to good process control and prevents open joints because the amount of flux on solder bumps 16 directly influences solder bump reflow. The flux plate and flux well 24 are designed for easy exchange and cleaning, without the need for special tools.

Flux dwell time is programmed in accordance with the type of flux used and its particular wetting capabilities. The amount of time spent applying flux to the chip directly influences system throughput. However, by performing the flux operation in parallel with other operations, such as picking die from wafers and placing fluxed die on substrates, the die fluxing step is removed from the critical processing path. Such parallel operations can increase the unit per hour rate (UPH) of the system by as much as 50%. The FCAM of this invention performs fluxing in parallel with the pick and place cycle to achieve improved throughput rates.

Die pick and place to a substrate is performed following flux dipping. Bond head 26 picks good die 12 from flux well 24 for presentation to an upward looking camera to perform vision alignment. The upward looking camera is described with reference to FIG. 4. The vision system determines the X, Y, and θ offsets from good die 12 to bond head 26. Based on this offset determination, an adjustment of the position of bond head 26 ensures that fluxed good die 12 is placed accurately on the substrate. Lighting is an important part of the vision process to ensure accurate location of the fluxed bumps, which can be challenging to basic vision systems.

Bond head planarity to the substrate affects accurate die placement. Small deviations can cause the die to shift during placement. Bond force control and bond force repeatability are factors in achieving accurate and repeatable placements. Closed-loop controlled bond force ensures highly accurate placements and repeatability, thus achieving a stable process and a high Process Capability index (Cpk).

After the substrates are populated with die, the carrier is either loaded back into a magazine or transported to a solder reflow oven. The offloading of carriers offers another opportunity for throughput gains. Improvement is realized if carriers can be exchanged sufficiently quickly to be done in parallel with the pick and place cycle. Although it exhibits fast action performance, the indexing of carriers operates smoothly to prevent die shifting. A preferred way of performing fast carrier exchange entails combining the carrier conveyor with a mechanical device. With this approach, the conveyor can be used to bring carriers to and from the die bonder system, but the faster mechanism can be used for rapid delivery of the carrier to the assembly area. By controlling acceleration and deceleration of the carrier mechanism motion, the fastest movements are possible without disturbing the placed die. Performing carrier exchange in parallel with the die pick and place cycle is especially important when there is a low number of die for each carrier. This is so because carriers with low numbers of die are exchanged frequently.

The final step of the flip chip die bonding assembly process is solder reflow. Solder bumps are reflowed in an oven with an inert atmosphere, creating a solder joint that also acts as the electrical interconnect. A typical reflow oven used in flip chip applications has multiple heat zones and can reach temperatures of up to 400° C. The actual reflow profile is a function of oven indexer belt speed and heat zone temperature settings. Carriers with reflowed chips are either loaded back into a magazine or transported to a next process step.

The dispense of underfill follows solder reflow. Underfill material is dispensed alongside the die, and the material is drawn between the die and the substrate via capillary action. Underfill material is used to protect the interconnect area from moisture. It also reinforces the mechanical connection between the substrate and the die. Underfill compensates for any difference in the thermal coefficient of expansion (TCE) between the chip and the substrate.

After underfill dispense is finished, the carrier is indexed into the post heat area. Post-heating allows the underfill material to finish flowing, and allows any air bubbles (voids) to escape, while keeping moisture content low. Having a separate post-heat station increases package reliability at no cost to system UPH.

After the underfill dispensing process is finished, the processed carriers are loaded into magazines or transported into a cure oven. Temperatures and dwell times depend on the type of underfill material used and the package size. Once the underfill is cured, the part is a complete, bonded, interconnected, packaged system.

The flip chip assembly machine offers several advantages. First, the flip chip assembly machine is designed with a main gantry and a substrate camera gantry that are configured to operate independently of each other and, respectively, support a die and a substrate camera for alignment purposes. Second, the flip chip assembly machine imparts motion to the flux reservoir by variable, uniform speed motor operation to allow for different motion speeds, depending on flux viscosity. Third, a flip-to-flux pick and place subassembly is configured to pick up a die and place it in flux independently of the operation of the main gantry. The main gantry is, therefore, made available to perform another task during the flux dwell time. Fourth, the substrate carrier conveyor operates in association with a walking beam to synchronize the movement of the substrates to that of the conveyor belts. The synchronism achieved allows rapid and controlled acceleration and deceleration of the substrate carrier to speed the movement of carriers into and out of the flip chip assembly machine. The synchronized movement also eliminates rubbing of the substrate carrier against the belt caused by a speed difference between them and thereby minimizes wear and particle generation.

Additional aspects and advantages of this invention will be apparent from the following detailed description of preferred embodiments, which proceeds with reference to the embedded and accompanying drawings.

### BRIEF DESCRIPTION OF THE DRAWINGS

FIGS. 1A, 1B, 1C, and 1D are simplified pictorial elevation views of a die picking and flipping process employed by operation of the FCAM.

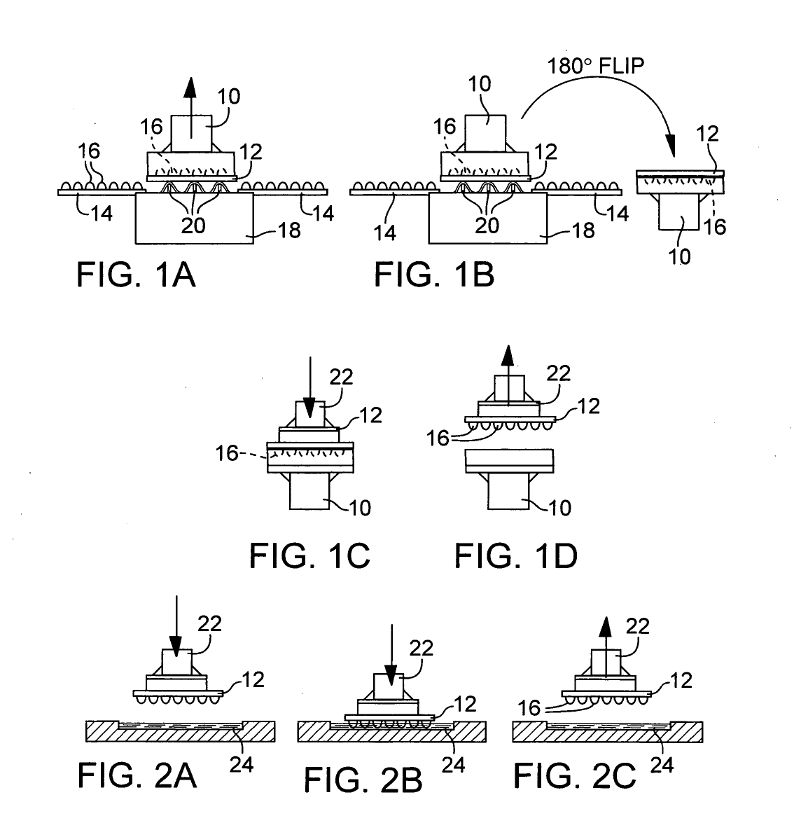

FIGS. 2A, 2B, and 2C are simplified pictorial elevation views of a die flux dipping process employed by the FCAM.

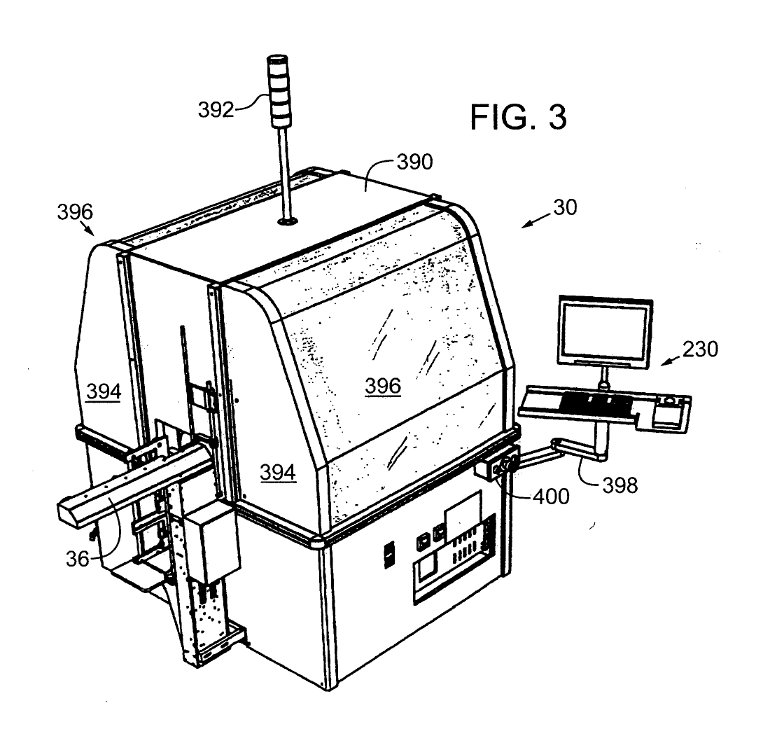

FIG. 3 is an isometric view of an embodiment of an FCAM of the present invention shown enclosed within its system cabinet.

FIG. 4 is a diagram of the FCAM of FIG. 3 with its system cabinet removed to reveal its main subassemblies.

FIG. 5 is an isometric view of a wafer handling subassembly of the FCAM of FIG. 4.

FIG. 6 shows an enlarged view of a needle array die ejector.

FIGS. 7A, 7B, and 7C are cross sectional schematic views showing the operational sequence of using the die ejector of FIG. 6 to release a die adhered to a sticky film.

FIG. 8 is an isometric view of a die flipper mechanism and a flip-to-flux mechanism that cooperate to pick a die from a wafer and manipulate the die into position for dipping in a flux well at a flux station.

FIG. 9 is an isometric view of a flux station that includes a flux well into which a die is dipped to apply flux to the solder bumps on the die.

FIG. 10 is an isometric view of a main gantry that spans the width and moves along the length of the FCAM to position the die pickup tool and its associated camera.

FIG. 11 is an enlarged isometric view of a θ-axis die pickup head and associated die pickup tools carried by the main gantry of FIG. 10.

FIG. 12 is an isometric view of the underside of a substrate gantry positioned below the main gantry and carrying the downward-looking substrate camera shown in FIG. 4.

FIG. 13 is an isometric view from one end of the substrate conveyor.

FIGS. 14 and 15 are isometric views of, respectively, the side and top of the conveyor of FIG. 13 showing the components of the walking beam mechanism.

FIG. 16 is an isometric view of the top of a tooling lift assembly that is embedded in the conveyor of FIG. 13 to lift the substrates off the conveyor belts.

FIGS. 17 and 18 are isometric views of, respectively, substrate magazine unloader/elevator and substrate magazine reloader-elevator subassemblies of the flip chip assembly machine of FIG. 4.

FIG. 19 is a block diagram of the control system governing the overall operation of the flip chip assembly machine of FIG. 4.

### DETAILED DESCRIPTION OF PREFERRED EMBODIMENTS

As described in the background of this invention, flip chips are small die that carry arrays of tiny balls of solder (solder “bumps”) that are precisely aligned with and placed on corresponding pads on the circuit substrate. The flip chip assembly machine places flip chips precisely onto the substrates. The flip chip-substrate assemblies are then delivered to an owner-provided downstream oven to reflow the solder bumps and thereby complete the attachment process.

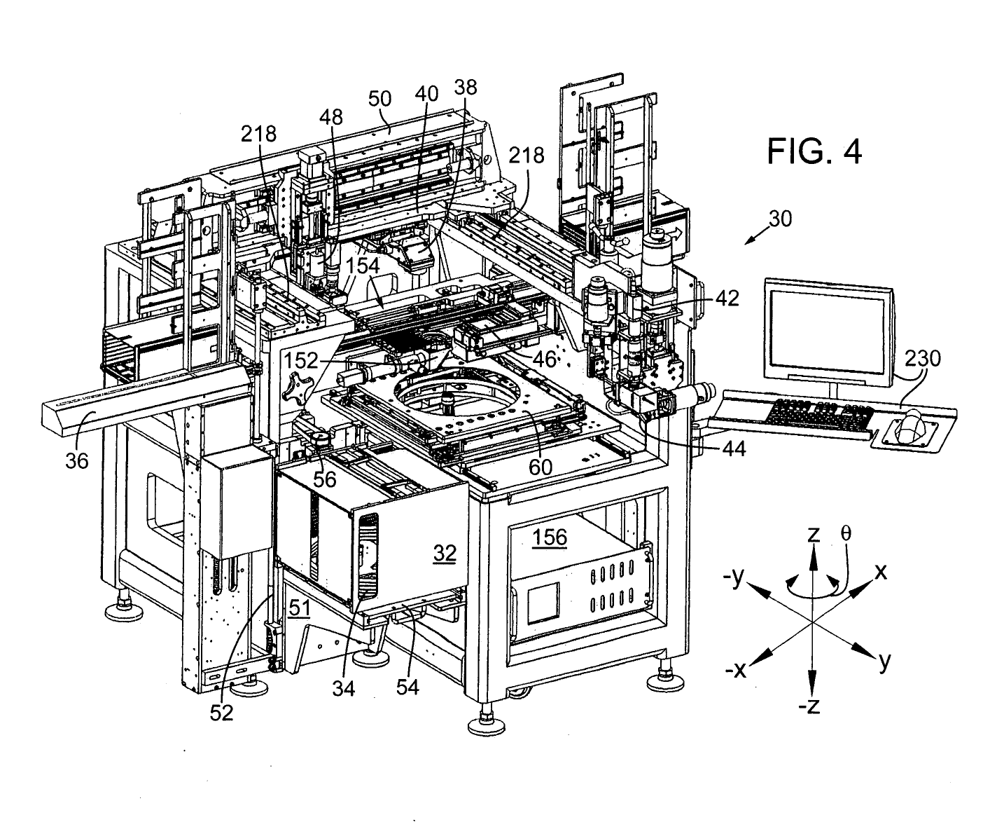

FIG. 3 shows the overall external appearance of an FCAM 30 in which the preferred embodiments of this invention are implemented.

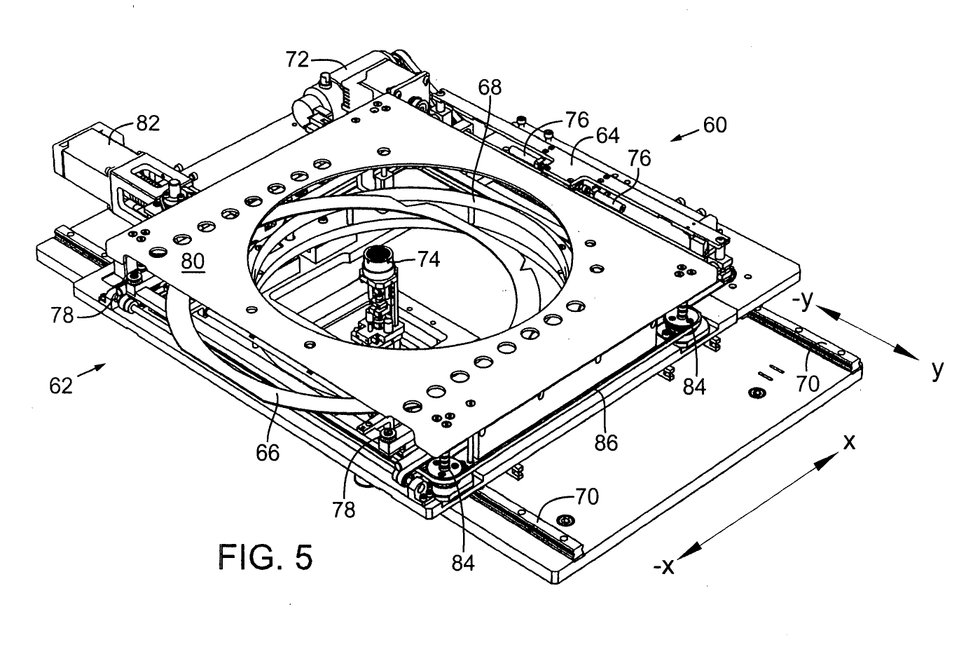

FIG. 4 shows an internal view of FCAM 30, the subassemblies and operation of which are described below. FCAM 30 accepts cassettes 32 of frame-mounted silicon wafers 34 that are diced into discrete flip chips. FCAM 30 further accepts magazines of substrates on which the flip chips are to be assembled. Substrates, or pallets containing a number of substrates, are placed in a loader 36 and are conveyed through FCAM 30 and positively locked into position for die placement. A substrate camera 38 mounted on a camera gantry 40 examines the substrates and precisely determines the position coordinates of the substrate pads. The solder bumps are applied to wafers 34 before dicing and are positioned on the “top” surface of the die. A vision system including a wafer camera 42 locates the positions of the solder bumps. A flipper mechanism 44 acquires each die and inverts it 180°, so that the solder bumps face down, in the correct orientation for placement onto the target substrate. The die is then placed briefly in a shallow flux well 46 to apply flux to each solder bump, facilitating the downstream solder-reflow process. A pick-and-place mechanism 48 mounted to a main gantry 50, and moving independently above substrate camera gantry 40, acquires the die from flux well 46. FIG. 4 shows wafer camera 42 and flipper mechanism 44 swung aside in a maintenance position for purposes of illustration to reveal flux well 46. Motions are described with reference to the X-, Y-, Z-, and θ-(theta) axes shown in FIG. 4.

FIG. 4 further shows a wafer cassette elevator 51 that is designed to accept all standard cassettes for 300 mm (12 in) or, optionally, 200 mm (8 in) wafer frames. The vertical motion of wafer cassette elevator 51 is constrained by a pair of anti-friction slides 52 (one shown), and an elevator platform 54 is positioned by a ball-bearing lead screw 56 that is rotated by a closed-loop stepper or servomotor (not shown). The top end of the range of motion of wafer cassette elevator 51 positions cassette 32 at a convenient loading elevation. The bottom end of the range of wafer cassette elevator 51 motion positions the top of cassette 32 below other moving parts of the machine to provide clearance. Between these extremes, cassette 32 is indexed from one wafer frame 34 to the next, positioning frames 34 in a programmed sequence so they can be withdrawn from cassette 32 for delivery to a wafer handling system 60 for processing. A fluidic shock-absorbing system (not shown) positioned at the bottom of the stroke of the cassette elevator cushions the descent, if the drive system should fail.

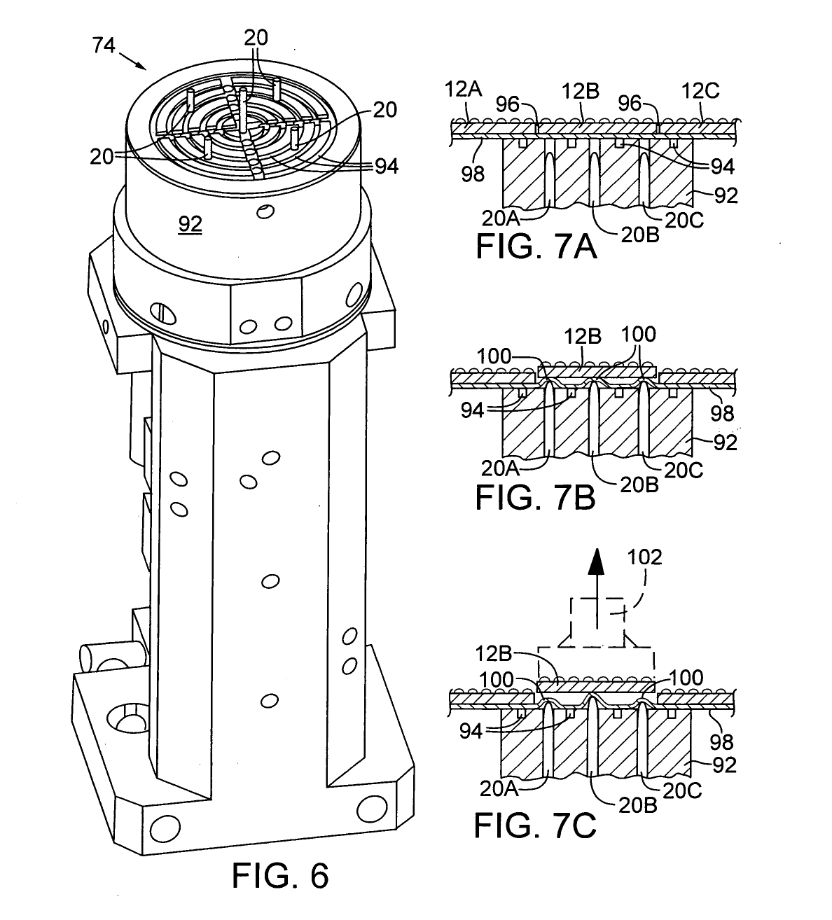

FIG. 5 shows further details of wafer handling system 60, which includes a wafer-frame holder 62 that moves along the ±X and ±Y axes, a wafer-fetch gripper device 64 that acquires wafer frames 66 from cassette 32 (FIG. 4), and a stretch ring 68 that applies tension to a sticky wafer frame film (not shown) on which the wafer rests. Wafer-fetch gripper device 64 later acts as a pusher to return wafer frames 66 to cassette 32. Stretch ring 68 provides a known elevation (Z-axis direction) for the wafers. The 300 mm (12 in) wafer-handling system can be modified to handle 200 mm (8 in) wafers by exchanging in the field a subassembly and a few change parts.

Wafer frame holder 62 is set on two pairs of rails 70 allowing motion in the X- and Y-axis directions (only Y-axis rails are shown). An X-axis servomotor 72 and Y-axis servomotor (not shown) drive ball screws (not shown) that move wafer frame holder 62 to locate each die on the wafer precisely over an ejector assembly 74 so that individual die can be acquired for processing. After being ejected by ejector assembly 74, each die is acquired by a vacuum tool on flipper mechanism 44 (FIG. 4), after which wafer frame holder 62 moves in preprogrammed X- and Y-axis amounts to bring the next die into position over ejector assembly 74.

Wafer-fetch gripper device 64 is sandwiched within wafer handling system 60 and is powered by a closed-loop stepping motor (not shown) to extend outwardly (in the “−X” direction) and pneumatically actuated by air cylinders 76 to grip the one of wafer frames 66 that is elevated to the correct position. The stepping motor then retracts wafer-fetch gripper device 64 (in the +X direction), to pull wafer frame 66 into position. FIG. 5 shows wafer frame 66 mostly pulled into position within wafer frame holder 62. During its motion, wafer frame 66 is supported and guided by rows of grooved rollers 78 (only two shown) on each side of wafer frame holder 62. When wafer frame 66 arrives at the correct position, a pair of pneumatically actuated clamps (not shown) lock it in position. Wafer-fetch gripper device 64 then releases wafer frame 66 and retracts to a “home” position that does not interfere with subsequent operations.

When wafer frame 66 is locked into position, a pressure plate 80 positioned above wafer frame 66 moves downward a short distance to bring the wafer frame sticky film into contact with stretch ring 68, which has a diameter that is halfway between the outer diameter of the wafer and the inner diameter of wafer frame 66. Pressure plate 80 continues pushing wafer frame 66 downward a pre-programmed distance to slightly tension and stretch the sticky film under the diced wafer. Pressure plate 80 is lowered by a closed-loop stepping motor 82 that rotates four jack-screws 84 (only two shown) that are synchronously linked by a drive chain 86. In some cases it may not be necessary to stretch the sticky film, so the stretching process is a machine option.

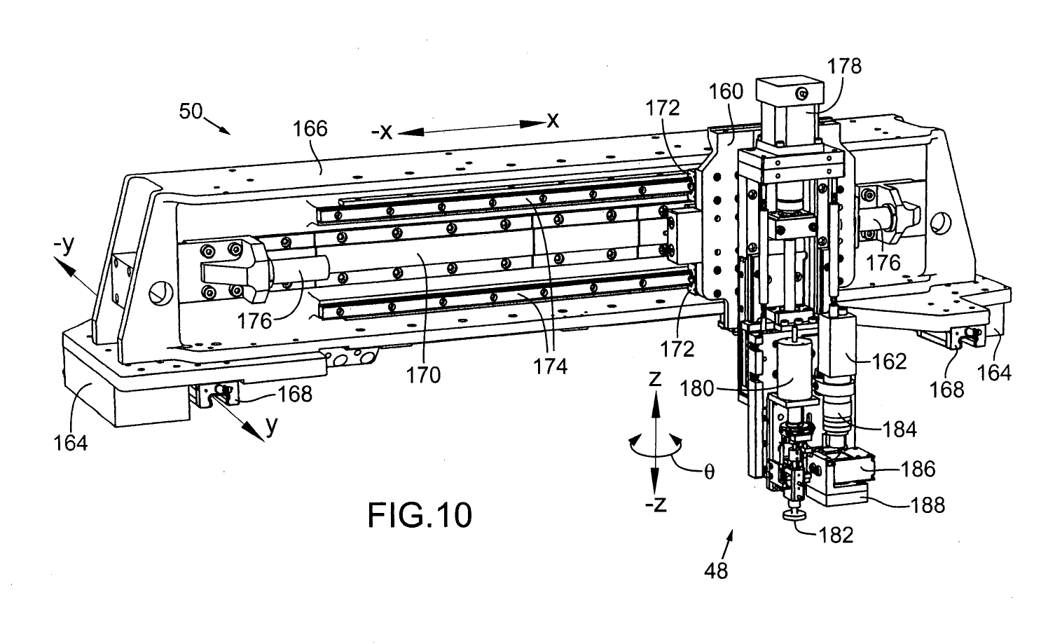

After each die is removed from wafer frame 66 and the next die is indexed into position, down-looking wafer camera 42 (FIG. 8) checks features on the die to be sure it is accurately placed. If there is an error, the X- and Y-axis servomotors of wafer handling system 60 make corrections as needed to place the die in the correct pickup location. Wafer camera 42 also examines each die for inspection marks that indicate a faulty component. If a die is so marked, wafer handling system 60 automatically indexes to the next die on the wafer. Wafer camera 42 has a programmable-intensity, light-emitting diode (LED) light source that provides uniform on-axis illumination of the wafer surface.

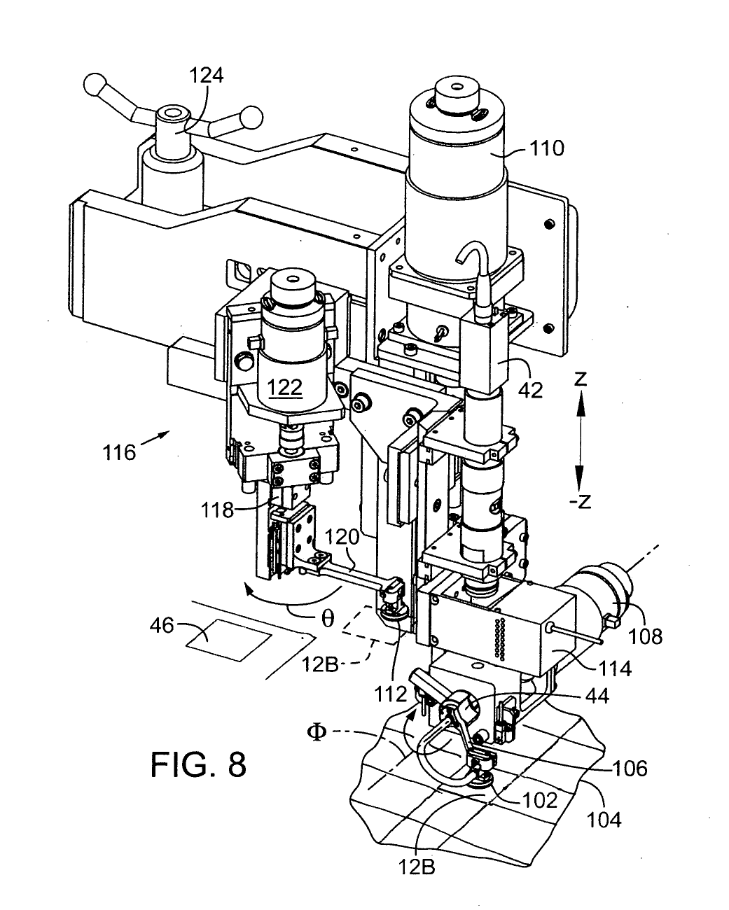

FIG. 6 shows further details of ejector assembly 74, which includes a servomotor driven vertical slide that accepts interchangeable ejector pins 20. Ejector pins 20 protrude from a dome 92 that includes annular vacuum channels 94 for holding the sticky film down while ejector pins 20 push upward. Preferably, the center one of ejector pins 20 moves farther upward than the surrounding ejector pins 20 move.

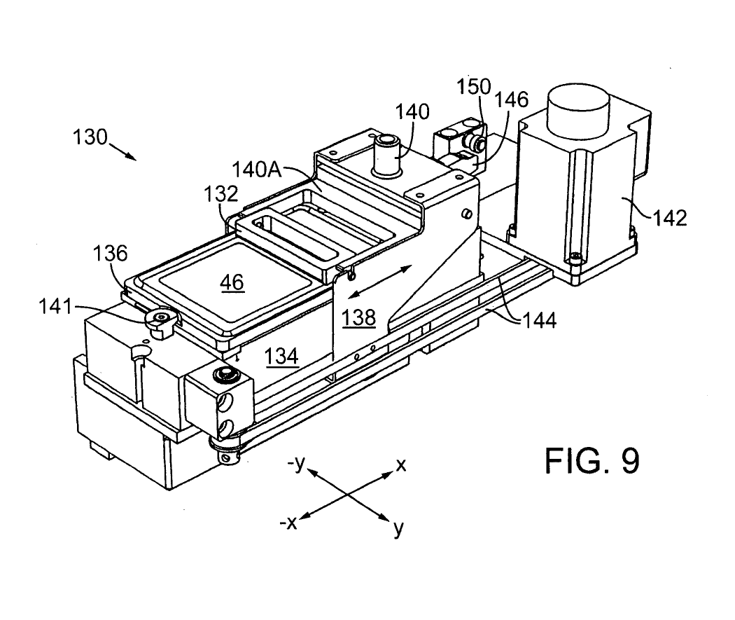

FIG. 7A shows die 12A, 12B, and 12C that are separated by fine saw cuts 96 and adhered to a sticky film 98, which is urged against dome 92 by vacuum pressure in vacuum channels 94. Die 12B represents one of a group of known good die on the diced wafer. Ejector pins 20A, 20B, and 20C are shown in their retracted positions. Ejector pin 20B represents the center-most of ejector pins 20.

FIG. 7B shows ejector pins 20A, 20B, and 20C protruding upward from dome 92 to form one or more “hills” 100 in sticky film 98 under die 12B, thereby reducing the effective area of sticky film 98 contacting die 12B so it can be readily picked from above by a vacuum tool 102 (FIG. 7C) on flipper mechanism 44 (FIG. 4). For ejecting very small die, only ejector pin 20B may be used; for larger die, ejector pins including 20A, 20B, and 20C may be used; and for very large die, independently actuated concentric arrays of ejector pins 20 may be used.

FIG. 7C shows ejector pin 20B protruding upward a distance farther than the protrusion distance of ejector pins 20A and 20C to break die 12B mostly free from hills 100 in sticky film 98 and causing die 12B to protrude upward from die 12A and die 12C, thereby facilitating the picking of die 12B by vacuum tool 102.

FIG. 8 shows further details of flipper mechanism 44 that acquires with vacuum tool 102 each die with bumps up, such as die 12B in a diced wafer 104, of which only a portion is shown. Flipper mechanism 44 moves vertically along a Z-axis and 180° rotationally about a φ-axis. An arm 106 is coupled to a φ-axis flipper motor 108, and an outer end of arm 106 includes a holder for interchangeable vacuum tools, such as vacuum tool 102.

With arm 106 rotated to the die picking position shown in FIG. 8 and vacuum pressure applied to vacuum tool 102, a flipper elevator motor 110 moves flipper mechanism 44 downward along the Z-axis to contact die 12B. Die 12B is contacted from above by vacuum tool 102 and from below by ejector assembly 74 essentially simultaneously. When a predetermined amount of vacuum pressure is sensed at vacuum tool 102 (signaling that die 12B is firmly gripped), flipper elevator motor 110 and ejector pins 20 (FIGS. 7A to 7C) move upward along the Z-axis simultaneously and at the same velocity. At a predetermined Z-axis elevation, vacuum pressure is released from vacuum channels 94 (FIG. 7C) and ejector assembly 74 retracts downward while vacuum tool 102 continues moving upward along the Z-axis. When flipper mechanism 44 has elevated sufficiently high for clearance, flipper motor 108 is actuated to impart “underhanded” (i.e., clockwise rotation to arm 106 such that die 12B rotates downward, swinging closely past wafer 104, and upward to a 180° inverted position (shown in dashed line) with solder bumps down and adjacent to a vacuum tool 112. Skilled persons will appreciate that Z-axis motion could be reduced and the rotation of arm 106 reversed (clockwise). In this particular design, however, clockwise rotation could cause interference with a light source 114 associated with wafer camera 42.

After flipper mechanism 44 has inverted die 12B, it is transferred to flux well 46 by either pick and place mechanism 48 associated with main gantry 50 (FIG. 4), or to minimize cycle time, preferably by a flip-to-flux mechanism 116. Flip to flux mechanism 116 elevates vacuum tool 112 along the Z-axis and 90° rotationally about a swing θ-axis in a horizontal plane. After flipper mechanism 44 positions die 12B just below vacuum tool 112, a pneumatic actuator 118 moves a swing arm 120 downward along the Z-axis a short distance such that vacuum tool 112 acquires die 12B. The vacuum pressure in flipper mechanism 44 vacuum tool 102 is then released and pneumatic actuator 118 moves vacuum tool 112 upward slightly. A θ-axis motor 122 swings die 12B 90-degrees horizontally into position above flux well 46. Pneumatic actuator 118 then lowers and presses die 12B into flux in flux well 46, releases the vacuum pressure on vacuum tool 112, and returns to dwell position above the die transfer point shown in dashed lines in FIG. 8.

A locking assembly 124 allows flipper mechanism 44, flip to flux mechanism 116, and their associated assemblies to be swung aside from the operational position shown to a position that allows access to other mechanisms of FCAM 30 that would, otherwise, be obscured.

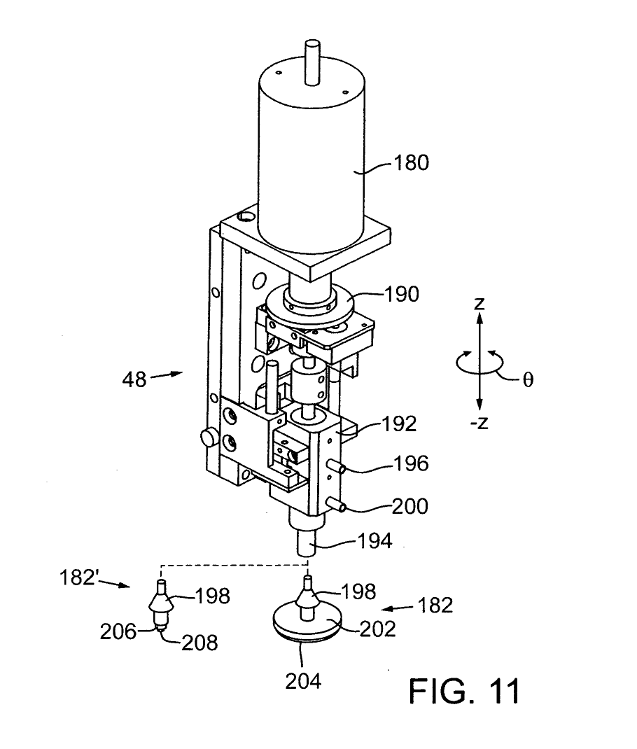

FIG. 9 shows a flux station 130 that facilitates consistent, uniform application of flux to solder bumps 16 of each die 12 processed by FCAM 30. Flux application is accomplished by reciprocating an open-bottom flux reservoir 132 over and back across flux well 46 to deposit a consistent layer of flux in the shallow depression forming flux well 46. Then, as described above, die 12B is placed in flux well 46 so that every solder bump touches the bottom of flux well 46 and, therefore, acquires the same amount of flux.

Flux station 130 includes a base 134 on which an interchangeable flux plate 136 is accurately mounted. Base 134 includes an upper surface that is manufactured to ensure accurate and permanent alignment that is parallel to the horizontal X- and Y-axes of FCAM 30. Each interchangeable flux plate 136 contains a shallow flux well depression sized to fit the largest die to be processed and having a depth suitable to match the solder bump sizes and flux properties employed. Flux well 46 depths preferably range from about 25 μm to about 250 μm (0.001 in to 0.01 in). Flux plates 136 are easily removed without tools.

The shallow depressions forming flux wells 46 in flux plates 136 can be formed by several techniques. One technique entails masking an area of an extremely flat metal plate and then plating (e.g., by electroless nickel plate process) all around the masked area to raise the surface. For example, after removal of the masking material, a 0.002-inch plating thickness creates a flux well of 50 μm in depth. A second technique entails masking all areas except the well area and etching to the desired depth by electrochemical milling processes. A third technique entails using an electrode of the same profile as that of the desired well shape and creating a depth by employing an electrical discharge machining (EDM) process. A fourth technique entails forming a rectangular through hole in a rectangular plate member of about 6 mm (0.24 in) in thickness. A rectangular piston having cross-sectional dimensions equal to the dimensions of the hole and having a length less than the 6 mm (0.24 in) thickness of the plate member is fit into the hole to plug it. Because its length is shorter than the thickness of the plate member, the piston plugging the hole forms a shallow recess in the member and thereby a flux well of a desired depth. The length of the plug can be set by a grinding operation to remove material, and the plugged hole can be sealed by a seal ring placed between the plug and the member from the bottom (exterior) side of the member.

For greater and less-critical depths, precision milling or grinding processes can create flux wells, which necessarily have rounded corners that require the wells to be considerably larger than the die, an undesirable result. All parts that can come in contact with flux are fabricated from or plated with corrosion-resistant materials.

A precision low-friction linear slide (not shown) is attached to base 134. A carriage 138, mounted on the slide, holds open-bottomed flux reservoir 132. A screw-actuated device 140 coupled to carriage 138 provides an adjustable spring force for pressing the bottom of flux reservoir 132 lightly against flux plate 136. The component 140A that retains flux reservoir 132 under spring force may be opened, either manually or automatically, to allow easy removal of flux reservoir 132 and flux plate 136. Preferably they can be removed individually or as a pair. A quick release latch 141 facilitates removal.

A closed-loop stepping motor 142 and timing-belt drive 144 move carriage 138 back and forth, causing flux reservoir 132 to reciprocate across flux well 46. The bottom perimeter surfaces or edges of flux reservoir 132 adjacent to flux plate 136 are polished to minimize friction and provide a good “doctoring” action, thereby depositing a smooth flux surface in flux well 46. A film of flux between the bottom perimeter surfaces of flux reservoir 132 and flux plate 136 functions as a lubricant between them. Stepping motor 142 provides control of flux reservoir 132 velocity over flux well 46. For example, if the flux rheology requires a low-shear doctoring effect, flux reservoir 132 can be advanced quickly then retracted slowly.

To further facilitate removal of interchangeable flux plate 135, a cammed lever 146 is coupled to flux reservoir 132. When stepping motor 142 moves flux reservoir 132 to a maximum +X-axis location, cammed lever 146 engages a wheel 150 that presses down on cammed lever 146, thereby raising flux reservoir 132 off flux plate 136 and facilitating its removal.

In use, flux reservoir 132 is partly filled with flux, and stepping motor 142 is cycled once to fill and smoothly doctor the flux in flux well 46 prior to placing die 12B in the flux. Flip-to-flux mechanism 116 (FIG. 8) places die 12B in the flux and then pick and place mechanism 48 associated with main gantry 50 (FIG. 4) positions die 12B on the substrate. As soon as the flux well area is clear, flux reservoir 132 is automatically cycled again in preparation for receiving the next die.

The following are some alternatives to the above-described preferred flux station embodiment. The motor could be one of a closed-loop stepper motor, a servomotor, a conventional direct-current (DC) motor, or an alternating-current (AC) motor. In any event, the motor facilitates maintaining constant velocity over the flux well and allows different velocities on the “fill” (advance) and “doctor” (retract) portions of the flux depositing cycle. A cable/capstan, a fast-pitch lead screw, a rack and pinion, a linkage, or any of other numerous devices for obtaining straight-line motion could replace the belt drive. A linear motor could be used, eliminating the need to convert from rotary to linear motion. Base 134 could incorporate a controlled heating device to raise the temperature of the flux, if necessary, to reduce its viscosity or improve its chemical activity. A practical range of temperatures is from 20° C. (68° F.) to 50° C. (122° F.). The base could also incorporate a cooling device to reduce the temperature of the flux. The adjustable spring force that presses the reservoir against the flux plate could be “fixed” to reduce cost.

An optional electrically heated block, lightly pressed against the bottom of the flux plate, heats the area of the flux well to facilitate dispensing and doctoring very viscous or waxy fluxes. Many fluxes require a finite amount of time to react with the solder bumps. If this reaction time is significant, the overall cycle time is reduced by having flip to flux mechanism 116 place a die in flux well 46 and then return to the dwell position. After the appropriate flux reaction time has elapsed, pick and place mechanism 48 associated with main gantry 50 (FIG. 4) then acquires the die and places it on the target substrate. If fast fluxes are used, however, flip-to-flux mechanism 116 may not be needed. Instead, pick and place mechanism 48 on main gantry 50 can acquire the die directly from flipper mechanism 44, touch the die briefly in the flux, and then place the die on the target substrate.

Somewhat similar fluxing systems employ air cylinders to provide motion, but velocities are not well controlled and results are inconsistent. For small die, a rotary system has been employed in which flux is applied to a slowly rotating disk that passes under a fixed doctor blade to control film thickness. This is impractical for large die (diameter becomes too large for practical application). It is very difficult to maintain an even film thickness at the tolerances required (approximately ±5 μm). It is also impractical to use low-viscosity fluxes and virtually impossible to match shear rates along the radius of the circular disk. Another prior design uses a fixed flux reservoir and an oscillating flux plate. Because the plate is moving, not the reservoir, it is difficult to keep the flux-well bottom accurately parallel to the X-Y machine axes, which is necessary to ensure that all solder bumps are coated equally.

Referring again to FIG. 4, after it has acquired a fluxed die from flux well 46, pick and place mechanism 48 on main gantry 50 cannot move the die directly to the substrate until the exact position of the die is ascertained to ensure correct placement. This is accomplished by moving the die from flux well 46 to a position over an up-looking camera 152, which locates printed fiducial marks on the die that relate to the solder bump positions. Up-looking camera 152 is attached to the front of a substrate conveyor assembly 154 that is positioned centrally within FCAM 30.

For a very small die (e.g., less than 2 mm×3 mm (0.08 in×0.12 in)), up-looking camera 152 can view the entire die. For a larger die, pick and place mechanism 48 positions the die so up-looking camera 152 first views one corner, then an opposite corner of the die. The camera-acquired data are then processed by an industrial PC 156 to direct pick and place mechanism 48 and main gantry 50 to align the die with the target substrate in X-, Y-, and E-axis directions. Up-looking camera 152 includes a programmable-intensity LED ring light source containing two rows of alternating red, blue, and green LEDs. The LEDs are controlled independently to change the illumination angle of the die. The intensities of the differently colored LED are also variable, in accordance with product-specific programming, to provide a wide range of light colors for maximizing image contrast.

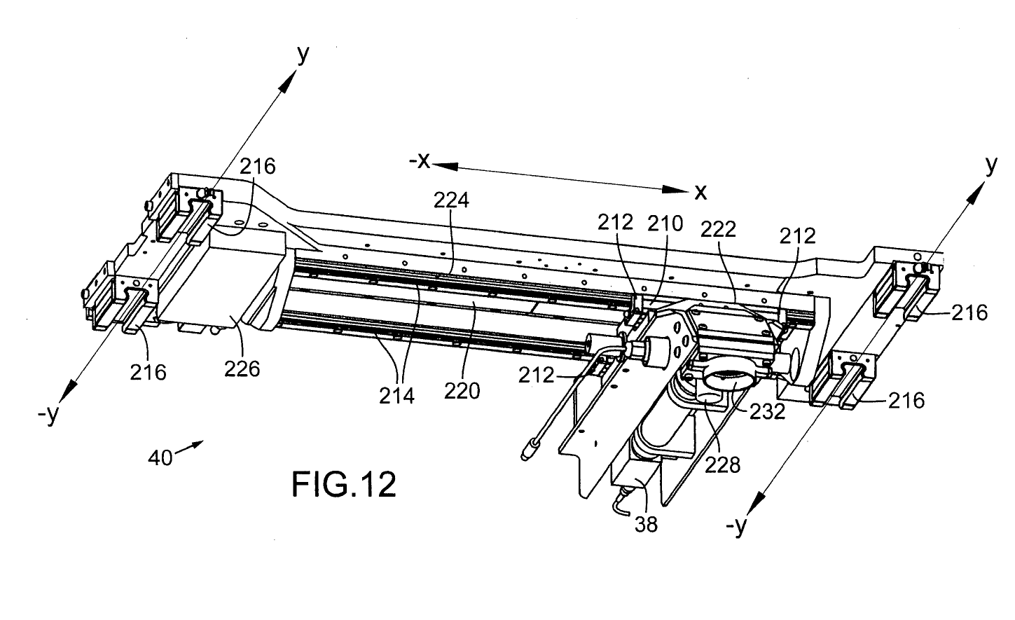

FIG. 10 shows further details of main gantry 50, which moves a carriage 160 that carries pick and place mechanism 48 for picking and placing die and a down-looking camera 162 for viewing the working area of FCAM 30. The X- and Y-axis motions of main gantry 50 are powered by linear motors. Y-axis motion employs two linear motors 164 running in synchronism, one on each side of main gantry 50. A lightweight, but stiff gantry beam 166 spans the width of main gantry 50 and moves on precise linear Y-axis bearing rails 168 that are positioned adjacent to Y-axis linear motors 164. Gantry beam 166 further includes an X-axis linear motor 170 for driving carriage 160 on X-axis bearings along X-axis rails 174. X-axis motion is limited by X-axis shock absorbers 176.

Pick and place mechanism 48 includes a Z-axis motor 178 and a theta-axis motor 180 for moving a vacuum pickup tool 182 in respective Z-axis and theta-axis directions. Down-looking camera 162 further includes a lens 184 for viewing the working area under vacuum pickup tool 182. The working area is illuminated selectively by an on-axis light source 186 and a ring light 188 having illumination characteristics similar to those of the ring light associated with up-looking camera 152 (FIG. 4). Ring light 188 is a shallow angle illuminator that provides off-axis illumination.

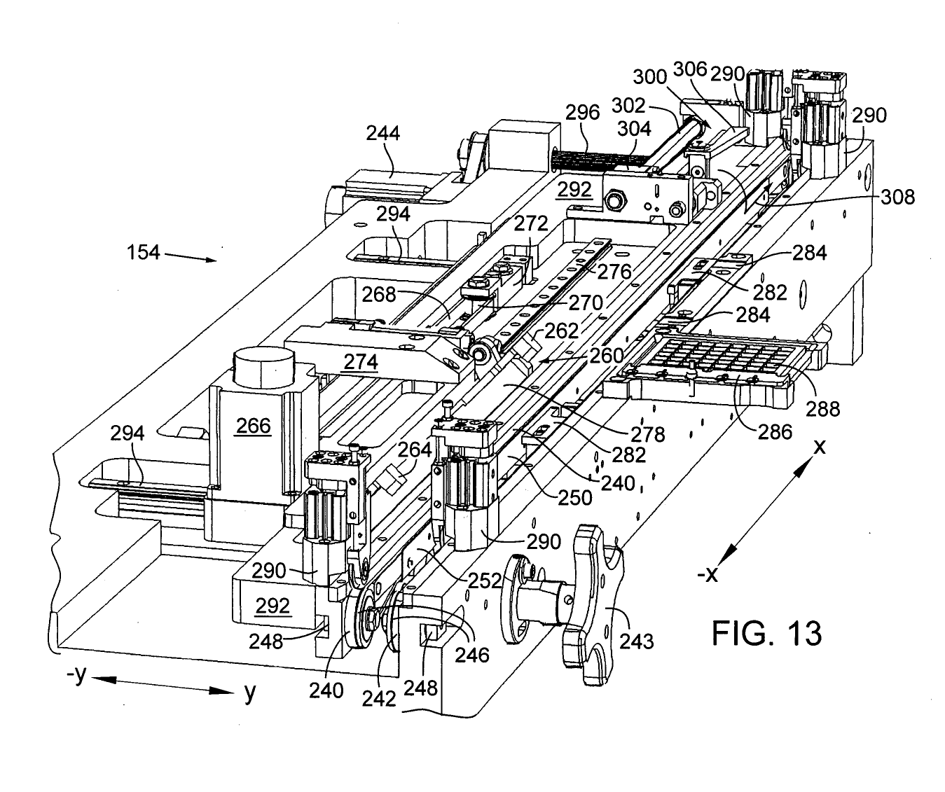

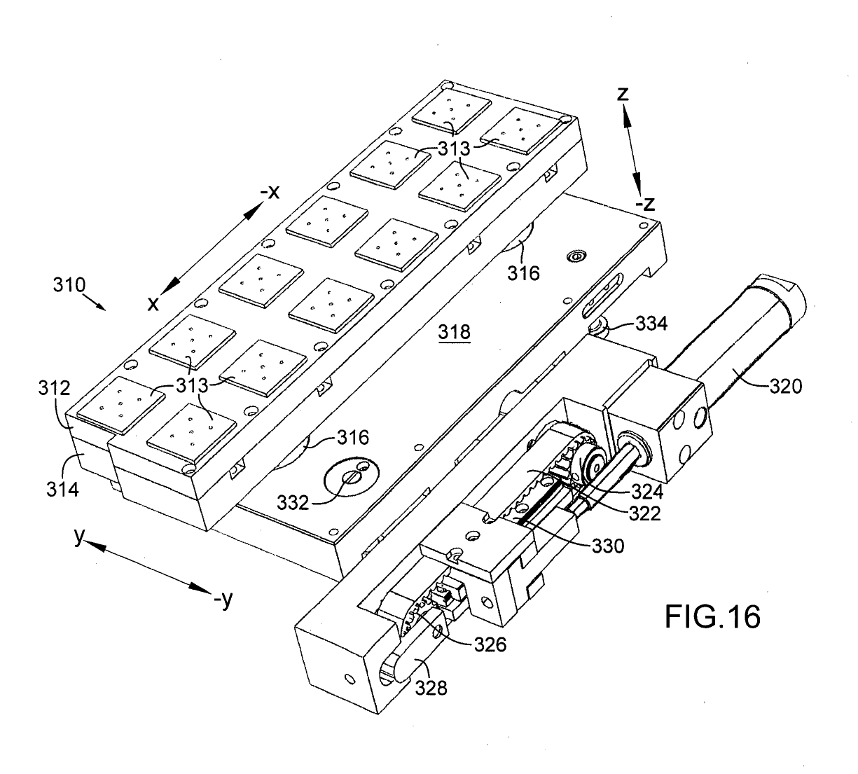

FIG. 11 shows further details of pick and place mechanism 48. The precise angular orientation of vacuum pickup tool 182 is measured by a precision glass-scale encoder 190 in a closed-loop relationship with theta-axis motor 180. Z-axis positioning of vacuum pickup tool 182 is augmented by a short, precision Z-axis slide 192. Vacuum pickup tool 182 is one of a set of interchangeable pickup tools, such as pickup tool 182′, that are held by vacuum pressure in a tool collet 194 that includes a conical seat. Vacuum pickup tools 182 and 182′ are hollow and employ controlled vacuum pressure supplied at a vacuum port 196 for picking up die. Vacuum pickup tools 182 and 182′ each further include a conical surface that mates with the conical seat in tool collet 194 for securing pickup tools 182 and 182′ by controlled vacuum pressure delivered to a vacuum port 200. Vacuum pickup tool 182 has a relatively large working end 202 that is preferably round, includes an inserted O-ring 204, and is suitable for picking and placing relatively large die. Conversely, vacuum pickup tool 182′ has a relatively small working end 206 that is preferably pointed, includes a rubber or elastomeric tip 208, and is suitable for picking and placing relatively small die. Interchangeable vacuum pickup tools, such as tools 182 and 182′ are stored in a tool holder described with reference to FIG. 14.

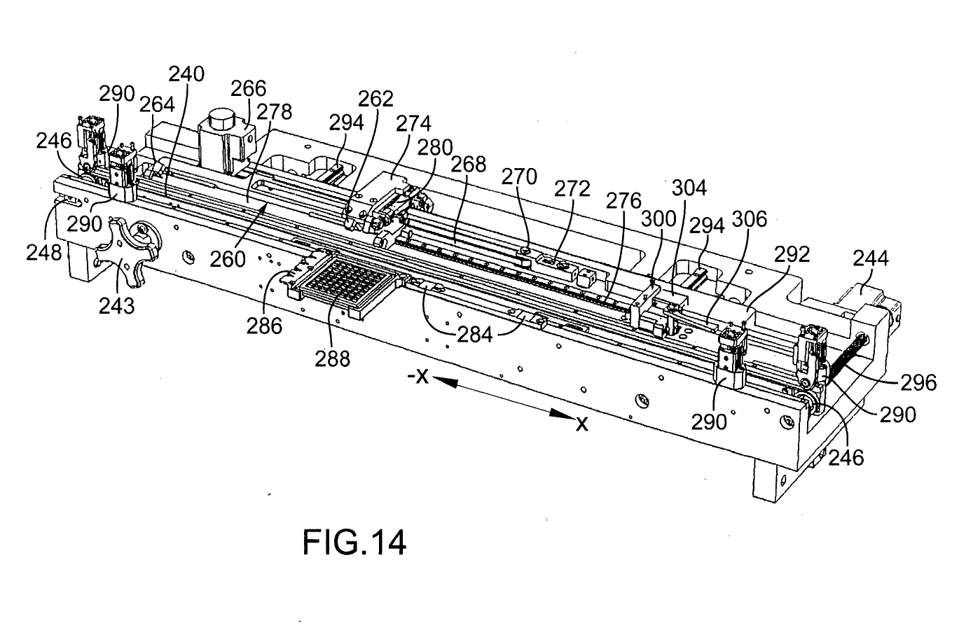

FIGS. 4 and 12 show substrate camera gantry 40, which moves along X-axis and Y-axis directions beneath main gantry 50. Down-looking substrate camera 38 is carried on a carriage 210 including X-axis bearings 212 that glide along X-axis rails 214. Substrate camera gantry 40 includes Y-axis bearings 216 that glide along Y-axis rails 218 (FIG. 4). X-axis motion of carriage 210 is accomplished by an X-axis linear motor 220, with the precise positioning of carriage 210 measured by an X-axis encoder 222 that senses an X-axis encoder scale 224. Y-axis motion of substrate camera gantry 40 is accomplished by a Y-axis linear motor 226.

The purpose of substrate camera gantry 40 is to save cycle time by positioning down-looking substrate camera 38 while main gantry 50 is busy elsewhere. Just as up-looking camera 152 determines the locations of the die fiducials with respect to die vacuum pickup tool 182 coupled to main gantry 50, down-looking substrate camera 38 determines the positions of corresponding fiducials on the substrates. Because different substrates may have different thicknesses, the focal plane of down-looking substrate camera 38 is varied by a motorized focus actuator 228 employing a DC motor and encoder. Initial focus may be set using [+] and [−] controls at an operator interface terminal 230 (FIG. 4), with which the initial focal plane position is captured in a part-specific program. As with other cameras in FCAM 30, a ring light 232 provides on-axis illumination of the substrates. While main gantry 50 is moving pick and place mechanism 48 between flux well 46 and two locations typically needed to view die fiducials, down-looking substrate camera 38 locates the correct substrate position for placing the die. As soon as substrate images are acquired, down-looking substrate camera 38 quickly moves in the −X direction to be clear of subsequent pick and place mechanism 48 operations. The substrate image locations are quickly processed, and main gantry 50 and pick and place mechanism 48 move as necessary in X-, Y-, Z-, and θ-axis directions to place the die in the correct location on the substrate.

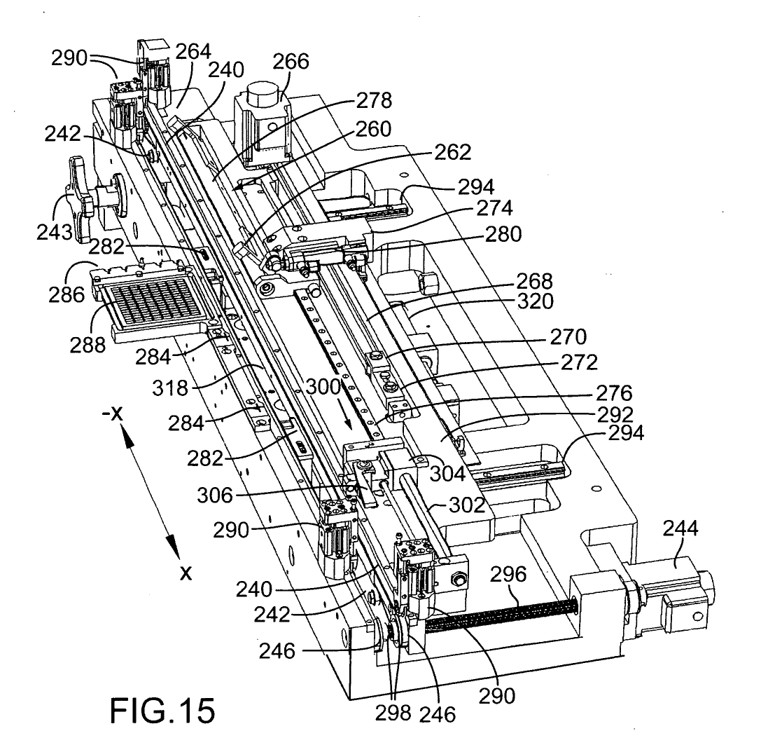

FIGS. 13, 14, and 15 show further details of substrate conveyor assembly 154, which carries substrates through FCAM 30 on a parallel pair of conveyor belts 240 and 242 that move at the same rate in the +X direction. Conveyor belt 242 is fixed in its X-axis position, while conveyor belt 240 can be adjusted in the Y-axis direction by turning a conveyor width knob 243. Regardless of the width adjustment (narrowest width is shown), conveyor belt 240 remains parallel to conveyor belt 242, to carry substrates having widths ranging from about 35 mm (1.38 in) to about 180 mm (7.09 in). The substrates can be carried on conventional stainless steel boats or carriers, of either flat or “J”-type, or they can be separate thin printed-circuit strips or boards. Conveyor belts 240 and 242 are narrow and support the substrates or substrate carriers by their edges. Optional pinch-rolls can be added to allow conveyor belts 240 and 242 to transport very thin or warped substrates. A single motor 244 simultaneously drives both belts, which are suspended between pairs of idler pulleys 246. The tension of conveyor belts 240 and 242 is adjustable by idler pulley tension adjustments 248. The functioning of conveyor belts 240 and 242 is augmented by conveyor belt support rails 250 (one shown) and conveyor belt guards 252 (one shown).

With particular reference to FIGS. 14 and 15, conveyor belts 240 and 242 are augmented by a reciprocating walking beam mechanism 260 that is positioned alongside conveyor belt 240 and moves along the X-axis parallel to the lengths of conveyor belts 240 and 242. Mounted to walking beam mechanism 260 is an interchangeable tool having fingers 262 and 264 that when deployed straddle the respective leading and trailing edges of the substrate or carrier. The spacing between fingers 262 and 264 is slightly greater than the length of the substrate or carrier. Skilled persons will appreciate that the fingers could also engage holes in carriers, if holes are made available for the purpose. In use, finger 264 of walking beam mechanism 260 quickly moves the substrate or carrier into an operating station while finger 262 simultaneously pushes the just-completed substrate or carrier out of the operating station. Conveyor belts 240 and 242 then carry the completed pallet or device farther downstream.

Walking beam mechanism 260 is reciprocated by a drive motor/encoder 266 that drives a drive belt 268, which is suspended around an idler puller 270 and tensioned by a guide belt tensioner 272. Drive belt 268 moves a walking beam support bracket 274 along a walking beam guide rail 276. Fingers 262 and 264 are coupled to a walking beam pivot bar 278 that is actuated by an air cylinder 280 to engage and disengage fingers 262 and 264 from the substrate or carrier.

The motion of walking beam mechanism 260 is more positive than could be achieved by conveyor belts 240 and 242 alone because they depend on friction to accelerate the substrate or carrier. Conveyor belts 240 and 242 and walking beam mechanism 260 are driven by servomotors or closed-loop stepping motors so acceleration and deceleration may be accurately controlled. Controlled acceleration minimizes the chance of dislodging assembled parts that are lightly adhered (e.g., prior to curing an adhesive or re-flowing solder). Moreover, controlled deceleration minimizes potentially harmful impact at the operating station “stop” position. Walking beam mechanism 260 can also move a carrier through multiple small steps, thus acting as an indexer. This is particularly useful when an operation is performed at several locations along a carrier and the operating equipment has limited mobility. Synchronously accelerating and decelerating conveyor belts 240 and 242 and walking beam mechanism 260 eliminates the wear and resultant particle generation that would occur if the carrier and conveyor belts moved at different speeds.

Substrate conveyor assembly 154 further includes stops with presence sensors 282 for properly positioning the substrates or carriers for processing at the operating station. Fiducial marks 284 provide operating station reference locations for down-looking camera 38 (FIG. 12). A tool change station 286 adjacent to the operating station includes a small grooved tool holder for holding vacuum pickup tools of various sizes, such as tools 182 and 182′ (FIG. 11) to cover die sizes from less than 1 mm (0.04 in) to about 53 mm (2.09 in) square. Defective parts or assemblies can be temporarily stored in a reject bin 288.

Referring to FIG. 15, conveyor belts 240 and 242 are secured to idler pulleys 246 by pinch roller assemblies 290. Turning conveyor width knob 243 turns a pair of width-adjusting, anti-backlash lead screws (not shown), one at each end of substrate conveyor assembly 154, that together move a conveyor width adjusting frame 292 along guide rails 294. Motor 244 rotates a splined drive shaft 296 that engages splined nuts 298 in idler pulleys 246 driving conveyor belts 240 and 242.

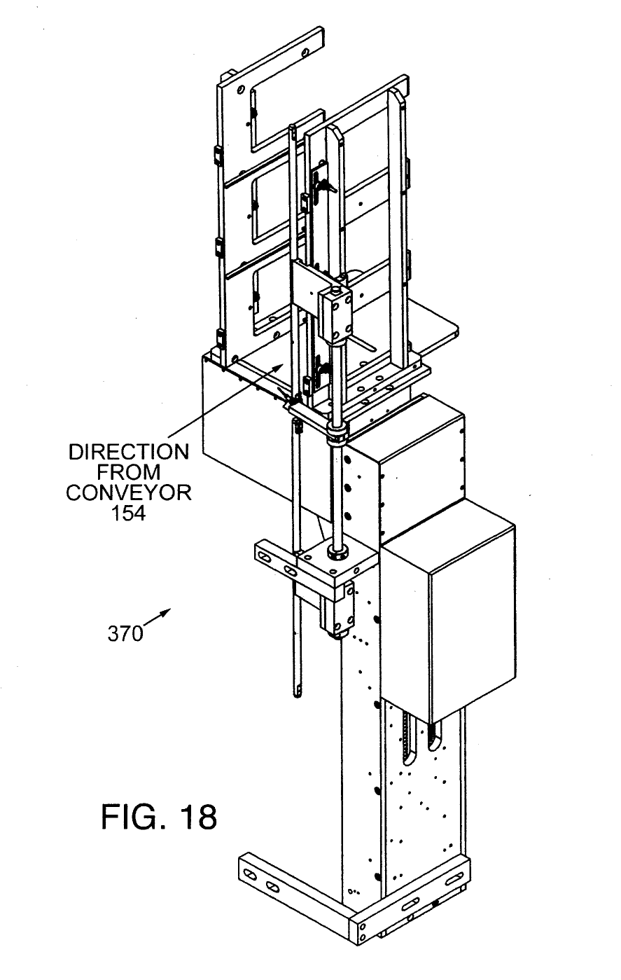

Substrate conveyor assembly 154 further includes a reloader mechanism 300 for reloading processed substrates or carriers back into magazines (FIG. 17) for further processing. An air cylinder slide 302 first moves a cam actuator 304, which swings a reloader finger 306 down 90-degrees in back of a completed substrate or carrier. As air cylinder slide 302 continues its motion, reloader finger 306 pushes the completed pallet or device several inches into the magazine. FIG. 13 more clearly shows a swing and push pathway 308 followed by reloader finger 306.

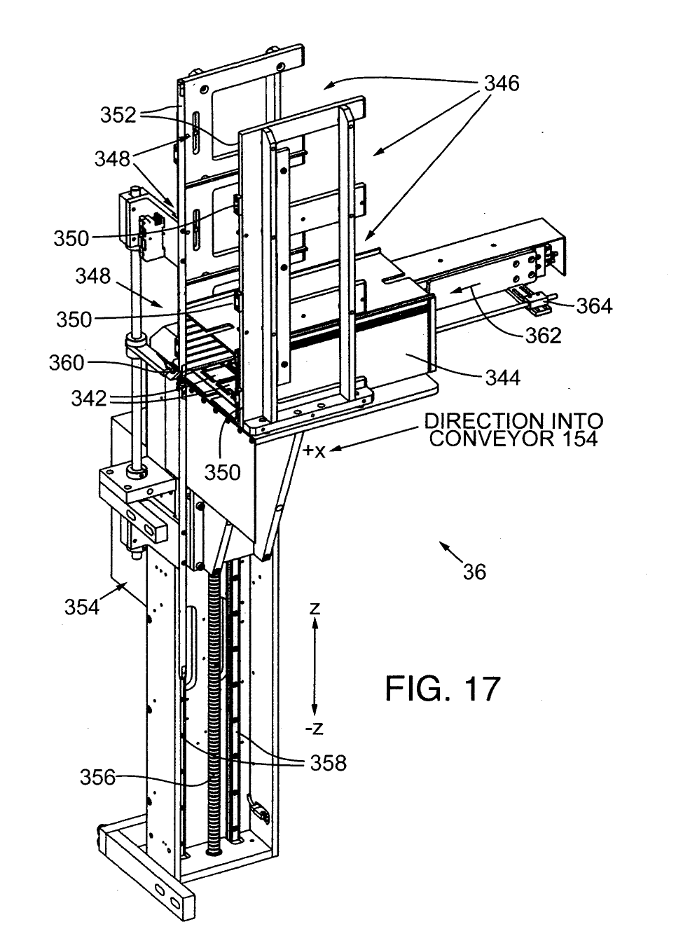

FIG. 16 shows a tooling lift mechanism 310 that is located beneath conveyor belts 240 and 242 for elevating and locking a tooling plate 312 at a predetermined Z-axis elevation slightly above conveyor belts 240 and 242. Tooling lift mechanism 310 supports and holds by vacuum pressure substrates, carriers, or devices at the operating station location for processing. Tooling plate 312 shown in FIG. 16 is a mid-sized example that is designed to hold twelve individual substrates 313 that are carried on a conventional Auer Precision “J” boat. Tooling plate 312 is supported by a spacer plate 314 that is coupled by linear guide shafts 316 to a lift table 318. Tooling plate 312 is raised by an eccentric cam (under lift table 318) that rotates 180° from bottom to top positions. Rotation of the cam is accomplished by an air cylinder 320 that pulls a cogged belt 322 that rotates a cogged pulley 324 that is coupled to the cam. Cogged belt 322 is supported by an idler pulley 326, tensioned by a tensioning clevis 328, and supported by a guide rail 330. (Portions of lift table 318 and air cylinder 320 are revealed in FIG. 15.) Alternative embodiments of tooling lift mechanism 310 may include a wedge system, screws, or any number of linkages driven by motors or pneumatic actuators. Substrates are preferably locked by vacuum pressure to tooling plate 312, although mechanical clamps or grippers could also be employed.

This embodiment of tooling lift mechanism 310 is advantageous because has a very low profile and can accurately position tooling plate 312 within 0.005 mm (0.0002 in) in a horizontal reference plane. An adjustable lift stop 332 and a fixed lift stop 334 ensure planarity and a travel limit. Tooling plate 312 is sufficiently wide to support the largest width tooling substrate conveyor assembly 310 can handle. Narrower tooling plates are preferably coupled to lift table 318 near the fixed (front) conveyor belt 242.

The operating sequence of tooling lift mechanism 310 starts at the completion of processing a carrier of substrates at the operating station:

1. With finger 264 of walking beam mechanism 260 engaging a next carrier, both walking beam mechanism 260 and conveyor belts 240 and 242 synchronously accelerate and then decelerate. At the completion of motion, the next carrier to be processed is in the operating station, and the previous carrier is at rest on the conveyor downstream of the operating station.

2. Tooling lift mechanism 310 rises to lift tooling plate 312 slightly off conveyor belts 240 and 242, and vacuum pressure is applied to secure the substrate carriers to tooling plate 312. At this time, stops 282 are actuated, and walking beam fingers 262 and 264 lift and retract to await the next carrier.

3. Conveyor belts 240 and 242 now advance at a low velocity to convey a new carrier into position against upstream stop 282 and to convey the processed carrier out of FCAM 30 to subsequent processes.

4. When the new carrier arrives at upstream stop 282, conveyor belts 240 and 242 stop and walking beam fingers 262 and 264 engage the front and rear ends of the new carrier awaiting a signal to advance.

5. When carrier processing is completed, the operating sequence returns to step 1.

FIG. 17 shows a rear view of substrate magazine elevator/loader 36. Substrates or carriers 342 are brought to FCAM 30 in metal or plastic magazines 344 that are supported by magazine carriers 346. Magazine carriers 346 are adjustable to accommodate different width magazines. Magazines 344 contain a series of shelves on each side for supporting multiple carriers 342. To improve throughput, FCAM 30 magazine elevator/loader 36 automatically transfers magazine carriers 346 sequentially onto substrate conveyor assembly 154 (FIGS. 13, 14, and 15) on demand. An operator of FCAM 30 can place a fresh magazine in one position and remove an empty magazine from a second position, while carriers in a third magazine are being loaded onto substrate conveyor assembly 154. Sensors 348 detect the presence of magazines 344 and are adjustable up and down. Forward stops 350 limit the forward travel of magazines 344, and retaining bars 352 prevent carriers 342 from drifting forward in magazines 344.

A stepper motor 354 (inside enclosure) drives a lead screw 356 that elevates magazines 344 to the load position shown in FIG. 17. Dual precision slides 358 and a load position photocell 360 ensure alignment of carriers 346 with substrate conveyor assembly 154. When aligned, a pusher 362 pushes carriers 342 one at a time out of magazines 344. Pusher 362 includes an adjustment 364 for magazine length and carrier height.

FIG. 18 shows a substrate magazine elevator/unloader 370, which may not be required in applications where processed carriers/substrates 346 are conveyed directly into a downstream oven. However, when needed, substrate magazine elevator/unloader 370 is very similar to substrate magazine elevator/loader 36, but lacks pusher 362. Instead, processed magazine carriers 346 are pushed into substrate magazine elevator/unloader 370 by reloader mechanism 300 (FIG. 15) on substrate conveyor assembly 154.

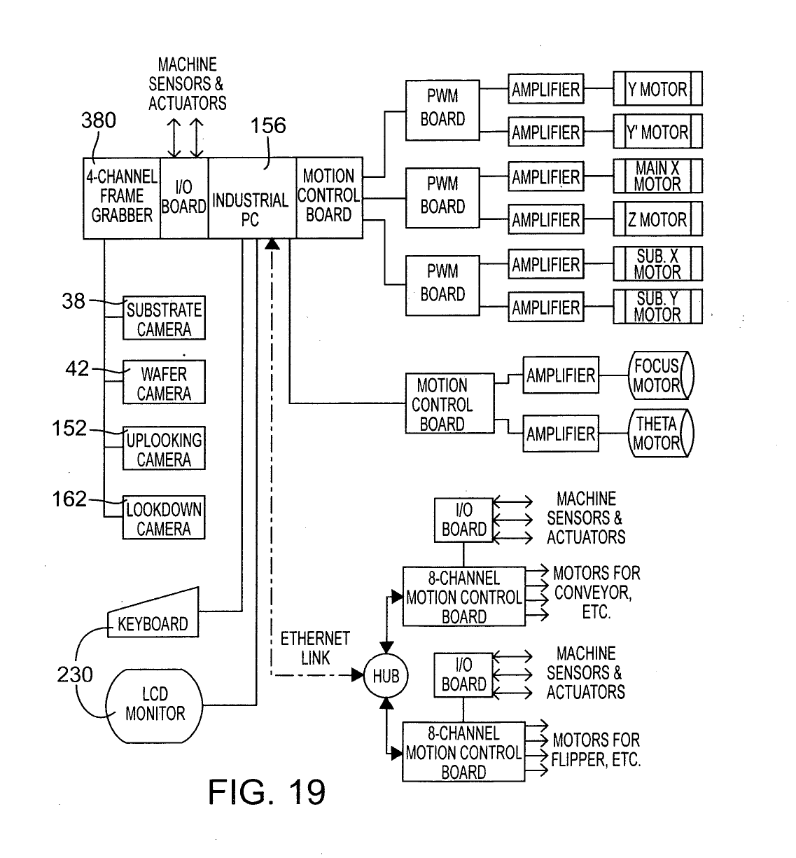

FIG. 19 shows a control system governing the overall operation of FCAM 30. Industrial PC 156 and ancillary process control boards respond to operational commands implemented in software and operational information provided by machine sensors to actuate the motors that position main gantry 50, camera gantry 40, and cameras 38, 42, 152, and 162. An Ethernet link connects industrial PC 156 to an Ethernet Hub for controlling machine subassembly operations such as those of substrate conveyor assembly 154, wafer handling system 60, die flipper motors 108, 110, and 122, and their associated sensors and actuators. Images acquired by the four cameras that contribute to die and substrate alignment and pick and place operations are processed by a four-channel image frame grabber 380 under control of industrial PC 156. A keyboard and a liquid crystal display (LCD) monitor constitute operator interface terminal 230 functions for industrial PC 156.

Referring back to FIG. 3, FCAM 30 is covered to prevent accidental contact with moving parts and ensure process cleanliness. A sheet-metal top “cap” 390 holds a multi-color indicator-lamp tower 392 to show machine status. A panel in cap 390 can be exchanged with a set of blowers and high efficiency particulate air (HEPA) filters, if desired by the user. From near the floor to “waist” level, the front and back of FCAM 30 have sheet-metal panels that are readily removable for access. The side panels are solid sheet metal from top to bottom, except for locations where the conveyor protrudes. Sliding or upward-swinging doors 394 with clear high-impact, static-dissipative-plastic windows 396 cover the front and rear of FCAM 30 from waist-level up to cap 390. At the front right of the machine, an articulated support 398 holds operator interface terminal 230, and a box 400 that contains Start, Stop and Emergency-Stop buttons.

Skilled workers will recognize that portions of this invention may be implemented differently from the implementations described above for preferred embodiments. For example, depending on specific product requirements, some components could be eliminated to reduce cost, though at the expense of throughput. As noted in previous sections, the substrate camera and its gantry and related controls could be eliminated, saving cost but increasing cycle time (reduce throughput). However, this may also increase accuracy somewhat by eliminating sources of error (e.g., substrate camera system resolution and substrate gantry position encoders). The flip-to-flux pick and place could be eliminated if the flux used was very fast acting. In this case, the main gantry would acquire the die directly from the flipper, move to and quickly place the die in the flux well, then immediately take the die to the up-looking camera. The conveyor walking-beam mechanism could be eliminated if carriers held a large number of substrates (carrier load/unload time would be a small proportion of the total time). With simple change tooling, the machine can be quickly reconfigured in the field to handle 200 mm (8 in) wafers, as well as the 300 mm (12 in) wafers for which it was designed. Some optional additions may be desired, such as heated substrate tooling.

The basic equipment can be used, with additions and/or subtractions of components, as a more conventional pick-and-place machine. In this case, the die (chips) are not “flipped” over, but simply picked from the wafer and placed on a substrate. For such applications, some of the changes might include optimizing the “Z”-stroke of the main gantry to pick directly from the wafer and adding a glue-application station either upstream or internal to the machine.

It will be obvious to those having skill in the art that many changes may be made to the details of the above-described embodiments without departing from the underlying principles of the invention. The scope of this invention should, therefore, be determined only by the following claims.

1. A specimen assembly machine, comprising:
a gantry support structure;
a specimen support and a substrate support spatially separated from each other;
a first gantry mounted for movement along the gantry support structure and including a beam to which a specimen pickup device is mechanically coupled, the beam having a length and the specimen pickup device mounted for movement along the length of the beam, the first gantry and specimen pickup device being operable for cooperative movements that enable the specimen pickup device to acquire a specimen at rest on the specimen support and deliver the specimen for placement on a substrate at rest on the substrate support;
a second gantry mounted for movement along the gantry support structure and including a positioning mechanism to which a substrate position-sensing device is mounted for movement to determine the position of a substrate at rest on the substrate support and onto which the specimen can be placed; and
the first and second gantries mounted for independent movements on the gantry support structure in response to respective first and second motive forces to enable non-interfering movements of the specimen pickup device and substrate position-sensing device in the determining of the position of the substrate and placement of the specimen on the substrate.

2. The specimen assembly machine of claim 1, in which the specimen is a bumped die.

3. The specimen assembly machine of claim 1, in which the specimen pickup device includes a vacuum pickup tool.

4. The specimen assembly machine of claim 3, in which the specimen is a bumped die.

5. The specimen assembly machine of claim 1, in which the substrate position-sensing device includes a camera.

6. The specimen assembly machine of claim 1, further comprising a camera and a two-source illuminator cooperating to view a working area associated with the specimen pickup device, and two-source illuminator operable for selective on-axis and off-axis illumination of the working area.

7. The specimen assembly machine of claim 6, in which the two-source illuminator includes a ring light to provide the off-axis illumination.

8. The specimen assembly machine of claim 1, in which the specimen support includes a flux station.

9. The specimen assembly machine of claim 1, in which the gantry support structure includes an upper set of parallel rails supporting the first gantry and a lower set of parallel rails supporting the second gantry, the upper and lower sets of rails being parallel to each other and offset from each other by an amount that permits movement of the second gantry relative to and beneath the first gantry along the gantry support structure.

10. A flux station that facilitates substantially uniform application of flux to solder bumps of a bumped die, comprising:
a flux plate coupled to a base and including a shallow depression that defines a flux well and is sized to hold a quantity of flux, the flux well having a flux well bottom on which the solder bumps of a bumped die placed in the flux well can rest;
an open bottom flux reservoir having a bottom perimeter surface and operatively connected to the base for translational movement of the bottom perimeter surface across the flux plate to allow flux contained by the flux reservoir to fill the flux well;
a drive mechanism operatively connected to the open bottom flux reservoir to impart to it reciprocal translational movement relative to the flux well, the open bottom flux reservoir and the flux well being set relative to each other such that, in response to the reciprocal translational movement, the bottom perimeter surface skims across flux residing in the flux well to establish a flux layer of substantially uniform depth for application to the solder bumps of a bumped die placed in the flux well; and
a variable velocity motor forming a component of the drive mechanism, the motor being controllable to operate at different velocities to move the open bottom flux reservoir at different speeds in different directions of translational movement.

11. The flux station of claim 10, further comprising:
a carriage providing a mounting for the open bottom flux reservoir and slidably mounted to the base, the carriage being mechanically coupled to and responding to motive force applied by the drive mechanism to impart the reciprocal translational movement to the open bottom flux reservoir.

12. The flux station of claim 10, further comprising a heating device thermally coupled to the flux plate to control the temperature of the flux.

13. The flux station of claim 10, in which the flux plate comprises a plug and a plate member that has a hole into which the plug is fit, the hole having a depth and the plug having a length that is shorter than the depth to form the shallow depression in the flux plate.

14. The flux station of claim 10, further comprising a force applying device operatively coupled to the flux reservoir to apply an amount of force that presses its bottom perimeter surface against the flux plate, the amount of force applied being sufficiently small to allow formation of a flux lubricant film between the bottom perimeter surface of the flux reservoir and the flux plate.

15. A specimen assembly machine, comprising:
a specimen support and a flux station;
a specimen flipper mechanism including an arm supporting a first specimen pickup tool and coupled to a drive device, the first specimen pickup tool configured to acquire a specimen positioned on the specimen support and the drive device causing the arm to move the acquired specimen to a specimen transfer location; and
a specimen pickup device including a second specimen pickup tool and movable to position the second specimen pickup tool at the specimen transfer location to effect a transfer of the specimen and to deliver the specimen to the flux station.

16. The specimen assembly machine of claim 15, in which the specimen pickup device comprises a flip-to-flux mechanism that includes a swing arm to which the second specimen pickup tool is attached, the flip-to-flux mechanism being configured to impart angular and linear motion to the second specimen pickup tool to acquire the specimen at the specimen transfer location and deliver the specimen to the flux station.

17. The specimen assembly machine of claim 16, in which:
the specimen has first and second major surfaces and the first specimen pickup tool acquires the specimen by contacting its first major surface; and
the arm moves at least in part by rotation the acquired specimen to the specimen transfer location to present the second major surface to the second specimen pickup tool.

18. The specimen assembly machine of claim 17, in which the flux station includes a flux well, and in which the specimen includes a bumped die having die bumps projecting from the first major surface so that the second specimen pickup tool delivers the bumped die with its die bumps facing the flux well.

19. The specimen assembly machine of claim 16, in which the specimen support comprises a specimen ejector assembly.

20. The specimen assembly machine of claim 15, further comprising:
a gantry support structure;
a gantry mounted for movement along the gantry support structure and including a beam to which the specimen pickup device is mechanically coupled, the beam having a length and the specimen pickup device being operable for cooperative movements that enable the second pickup tool to acquire the specimen at the specimen transfer location and deliver the specimen to the flux station.

21. The specimen assembly of claim 20, in which the specimen pickup device comprises a pick and place mechanism that is configured to impart angular and linear motion to the second specimen pickup tool.

22. The specimen assembly machine of claim 20, in which the specimen support includes the first specimen pickup device.

23. The specimen assembly machine of claim 20, in which:
the flux station includes a flux well;
the specimen has first and second major surfaces and the first specimen pickup tool acquires the specimen by contacting its first major surface; and
the specimen includes a bumped die having die bumps projecting from the first major surface so that the second specimen pickup tool delivers the bumped die with its die bumps facing the flux well.

24. The specimen assembly machine of claim 20, in which the specimen pickup device comprises a flip-to-flux mechanism to which the second specimen pickup tool is attached, the flip-to-flux mechanism operating independently of the gantry along the gantry support structure.

25. A specimen assembly machine, comprising:
a specimen conveyor moving in a direction along an axis in response to a conveyor device mechanism, the specimen conveyor including a carrier surface on which a specimen rests as it is transported by the specimen conveyor, the specimen having leading and trailing edges separated by a length;
a reciprocating walking beam mechanism moving along the axis in response to a walking beam drive mechanism, the walking beam mechanism including first and second fingers that are spaced apart by a distance along the length of the specimen and, when deployed, extend transversely of the first axis;
an actuator for selectively deploying the first and second fingers so that at least one of them engages the specimen; and
a controller operatively associated with the conveyor and walking beam drive mechanisms to provide synchronous acceleration and deceleration of the specimen conveyor and walking beam mechanism to provide controlled variable speed movement of the specimen conveyor without slippage of the specimen on the carrier surface while the first and second fingers are deployed.

26. The specimen assembly machine of claim 25, in which the specimen has edges and in which the specimen conveyor comprises two spaced-apart belts that define a split carrier surface supporting the specimen by its edges.

27. The specimen assembly machine of claim 25, in which the specimen includes holes and in which, when deployed, the first and second fingers engage the holes.

28. The specimen assembly machine of claim 25, in which the first and second fingers are spaced apart by a distance substantially equal to the length of the specimen, and in which, when deployed, the first and second fingers straddle the respective leading and trailing edges of the specimen.

29. The specimen assembly machine of claim 25, in which the first and second fingers are coupled to a walking beam pivot bar and the actuator comprises a fluid cylinder coupled to the walking beam pivot bar, the walking beam pivot bar pivotally moving in response to extension of the fluid cylinder to deploy the first and second fingers.

30. The specimen assembly machine of claim 25, in which one or both of the conveyor and walking beam drive mechanisms comprise servomotors.

31. The specimen assembly machine of claim 25, in which one or both of the conveyor and walking beam drive mechanisms comprise stepper motors.

32. The specimen assembly machine of claim 25, in which the specimen includes one of a device carrier or a substrate.

33. The specimen assembly machine of claim 32, in which the device carrier carries a die positioned on a substrate.
